(19) United States
(12) Patent Application Publication
(10) Pub. No.: US 2006/0252469 A1
(43) Pub. Date: Nov. 9, 2006

(54) Shut down mechanism for handheld device

(76) Inventor: Roger Lu, Shen Keng Hsiang (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/124,039

(22) Filed: May 9, 2005

(51) Int. Cl. H03K 5/00

(52) U.S. Cl. 455/575.1; 455/90.3

(57) ABSTRACT

A shut down mechanism for handheld devices is disclosed. The shut down mechanism for handheld devices consists of a fixing part, a magnetic object and a magnetic sensor. The fixing part is disposed on a handheld device for fixing batteries of the handheld device, the magnetic object is arranged on the fixing part and the magnetic sensor is set on the handheld device. When the fixing part is rotated for replacing batteries, the magnetic sensor detects magnetic power from the magnetic object and sends a signal to a central processing unit in the handheld device for running shut down procedure. Thus when users replace batteries of handheld devices without turning off the handheld device, the shut down procedure is executed automatically so as to avoid malfunction or damage of the handheld device.

### BACKGROUND OF THE INVENTION

The present invention relates to a shut down mechanism, especially to a shut down mechanism for handheld device that makes the replacement of batteries of handheld devices faster and more convenient.

Due to fast development of information technology, technology products with continuous changes and improvement are bringing a profound impact on of people's living, work and entertainment. They not only solve our daily problems but also satisfy our demands and needs. Especially electronics, make our lives more interesting. Nowadays, following the trend of the times, the design concept of modern electronic appliances is compact for the convenience of portability. For example, the cassette tape walkman in early days is replaced by the flash disk nowadays while recorders are replaced by digital recording pens. Most of handheld devices are designed based on such concept. There are various kinds of handheld devices available on the market now such as PDA (personal digital assistant) or mobile phones.

What these handheld devices have in common is the use of batteries for supplying power of the devices. While changing batteries, the handheld devices need to be shut down first for preventing damage or loss of data to the devices. However, there are always some silly users who replace the batteries directly without shutdown of the handheld device first. Thus when the handheld device is turned on again, the information may have errors or losses. Or even worse, the handheld device is out of order. If the handheld devices can remind users to run shut down procedure before changing the battery or even can automatically run the shut down procedure without manual operation so as to avoid any possible damage or data losses of the handheld devices.

### SUMMARY OF THE INVENTION

It is therefore a primary object of the present invention to provide a shut down mechanism for handheld devices that automatically shuts down the handheld device when a battery of the handheld devices is replaced. The device makes the handheld device more convenient and helpful for users.

It is another object of the present invention to provide a shut down mechanism for handheld devices that fixes a battery firmly in a handheld device so as to prevent the battery from falling off.

It is a further object of the present invention to provide a shut down mechanism for handheld devices that prevents external things from infiltrating into the handheld device and having effect on the handheld device.

A shut down mechanism for handheld devices in accordance with the present invention is composed by a fixing part arranged on a handheld device for fixing a battery of the handheld device; a magnetic object disposed on the fixing part and a magnetic sensor on the handheld device, corresponding to the magnetic object. When the fixing part is rotated for changing the battery, the magnetic object corresponds to the magnetic sensor so that the magnetic sensor detects magnetic power from the magnetic object and sends a signal to a central processing unit in the handheld device. After receiving the signal, the central processing unit runs the shut down procedure. Therefore, while changing the battery of the handheld device, the present invention automatically shuts down the handheld device. It's quicker and more convenient for users to replace batteries.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view of an embodiment in accordance with the present invention before replacement of a battery;

FIG. 2 is a perspective view of an embodiment in accordance with the present invention while replacing a battery;

FIG. 3 is a block diagram of an embodiment in accordance with the present invention while replacing a battery;

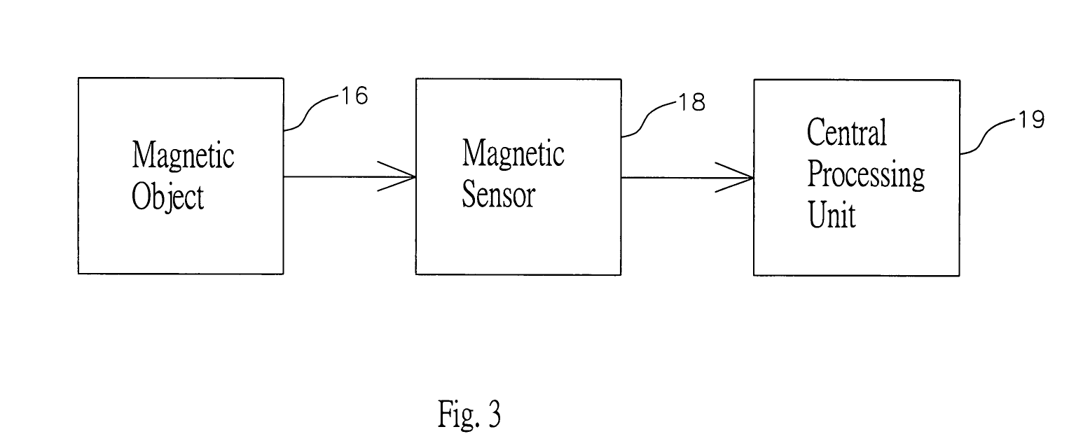

FIG. 4 is a perspective view of an embodiment in accordance with the present invention while taking out a battery; and

FIG. 5 is a perspective view of a battery of an embodiment in accordance with the present invention.

### DETAILED DESCRIPTION OF THE PREFFERED EMBODIMENT

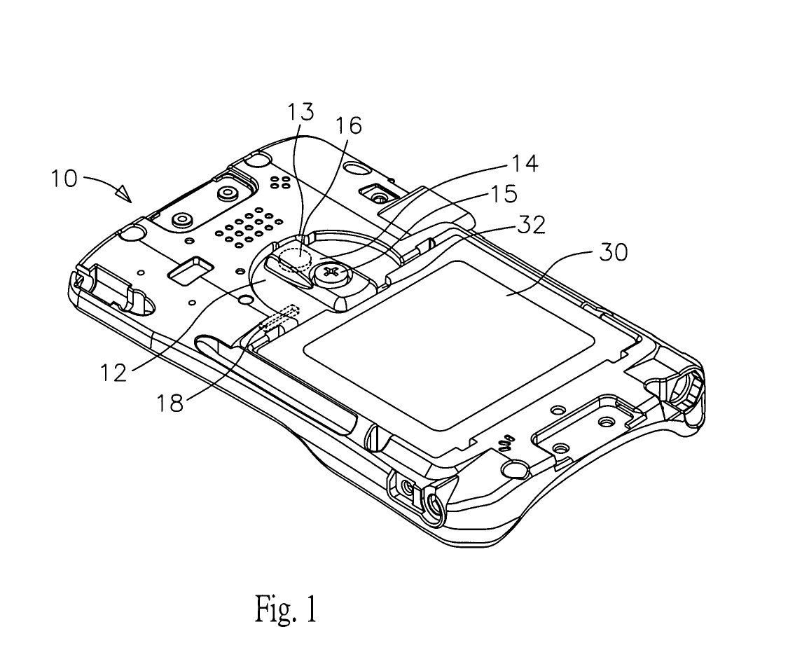

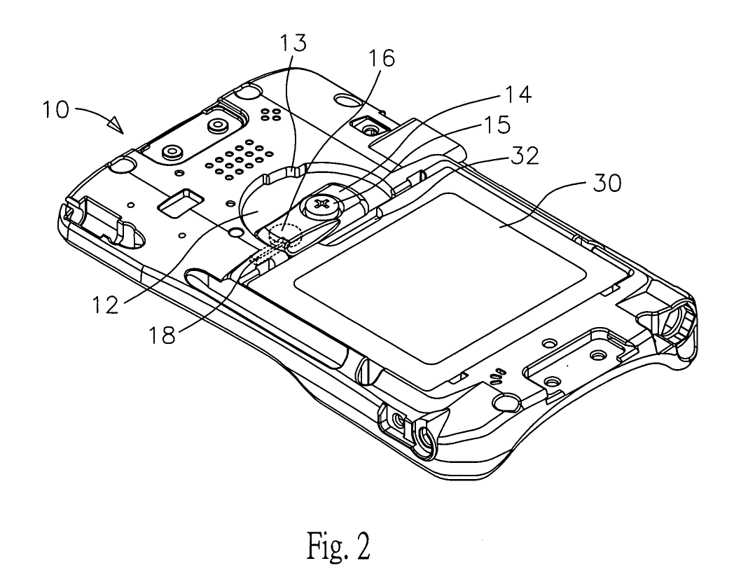

Refer to FIG. 1 & FIG. 2, both are perspective view of an embodiment before and while changing a battery in accordance with the present invention. The present invention arranged on a handheld device 10 that may be a mobile phone or a personal digital assistant (PDA) consists of a fixing part 14, a magnetic object 16 and a magnetic sensor 18. The fixing part 14 is disposed on and rotatable inside an assembling slot 12 on the handheld device 10 by a screw 15. Thus the fixing part 14 is a rotating part while the assembling slot 12 is in arched shape for accommodating the fixing part 14. A locating block 13 is installed inside the assembling slot 12 for fixing the rotating fixing part 14. The magnetic object 16 is disposed on the fixing part 14 while the magnetic sensor 18 is arranged on the handheld device 10. The magnetic object 16 can be a magnet.

As shown in FIG. 1, when a battery 30 is disposed inside the handheld device 10, the battery 30 is fixed by rotating one end of the fixing part 14 into a fixing slot 32 of the battery 30. When an user rotates the fixing part 14 to fix the battery 30, the fixing part 14 leans against the locating block 13. While user wants to change the battery 30, he only needs to rotate the fixing part 14 into the position as shown in FIG. 2, rotating the fixing part 14 out of the fixing slot 32 so as to take out the battery 30.

When the fixing part 14 is rotated to the position shown in FIG. 2, the magnetic object 16 corresponds to the magnetic sensor 18. Then the magnetic sensor 18 detects magnetic power from the magnetic object 16 and sends a signal to a central processing unit 19 in the handheld device 10 for running shut down procedure. Thus the data inside the handheld device 10 won't get damage or losses when the user take out the battery 30 and further without any effect on the handheld device 10 while the handheld device 10 is re-booted. Therefore, there is no additional operation for the user to run the shut down procedure. It's convenient for users to replace the battery 30.

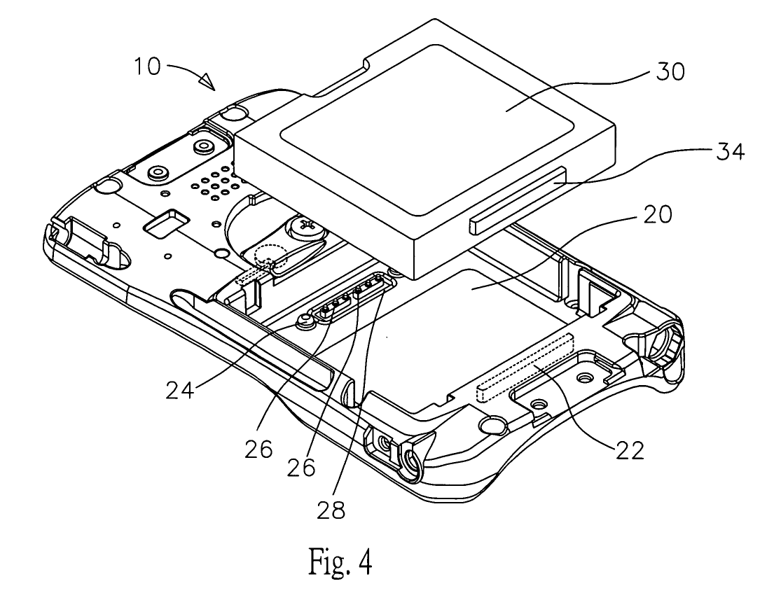

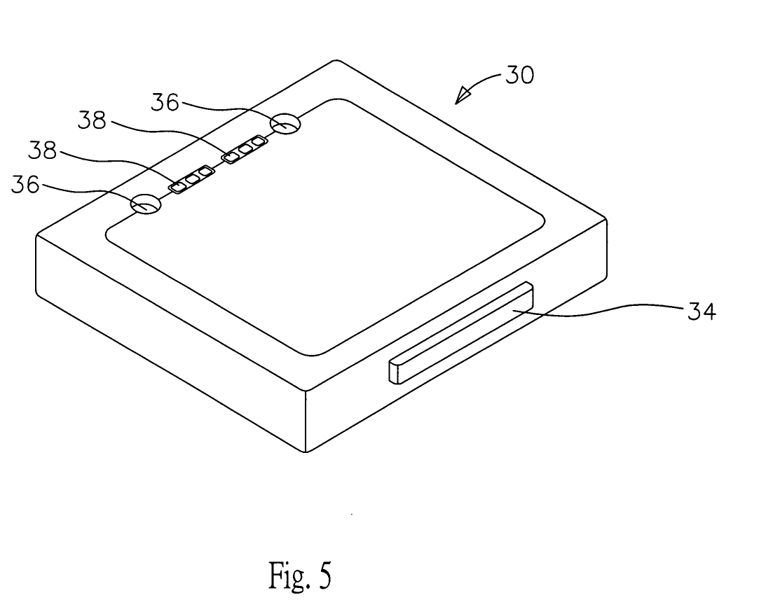

Refer to FIG. 4 & FIG. 5, a projective block 34 is arranged on the bottom of the battery 30 for fixing the battery 30 firmly on the hand held device 10 while a corresponding groove 22 is disposed on the bottom of an accommodating socket 20. Moreover, a plurality of projecting post 24 is arranged on the accommodating socket 20 and a plurality of holes 36 corresponding to the projecting post 24 is mounted on the battery 30. When the battery 30 is arranged inside the accommodating socket 20, the battery 30 is inclined in a certain angle so as to make the projective block 34 insert into the groove 22. At this moment, the holes 36 of the battery 30 also match the projecting posts 24 of the accommodating socket 20. Therefore, the battery 30 is fixed firmly in the handheld device 10 to prevent any negative effect of the handheld device 10 caused by the falling of the battery 30.

In addition, a waterproof bar 28 is disposed on outer side of electrodes 26 on the accommodating socket 20 so as to prevent something such as liquid or dust from infiltrating into the electrodes 26 and lead to damage or bad contact of the electrodes 26 and electrodes 38 of the battery 30. Or the external things may enter inner side of the handheld device 10 and cause damages. Therefore, the waterproof bar 28 avoids possible damages of the handheld device 10 and the battery 30 such as short circuit raised by external things thus further protects users.

In summary, a shut down mechanism for handheld devices in accordance with the present invention includes a fixing part with a magnetic object thereof. When the fixing part is rotated for replacing a battery, the fixing part is moved to the position that the magnetic object corresponds to a magnetic sensor on the handheld device. The magnetic sensor detects magnetic power from the magnetic object and sends a signal to a central processing unit of the handheld device. After receiving the signal, the central processing unit runs the corresponding shut-down procedure. Users don't need to shut down the handheld device by manual operation while the handheld device automatically shuts down. It's faster and convenient for users to change batteries and data damages or losses that has effect on the handheld device is also avoided.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A shut down mechanism for handheld devices comprising:
a fixing part disposed on a hand held device for fixing a battery of the hand held device;
a magnetic object arranged on the fixing part; and
a magnetic sensor installed on the handheld device;
when the fixing part is rotated for taking out the battery, the magnetic object corresponds to the magnetic sensor so that the magnetic sensor sends a signal to a central processing unit in the handheld device for running a corresponding shut-down procedure.

2. The device as claimed in claim 1, wherein the fixing part is a rotating part.

3. The device as claimed in claim 1, wherein the fixing part is disposed on an assembling slot of the handheld device.

4. The device as claimed in claim 3, wherein a locating block is disposed on the assembling slot.

5. The device as claimed in claim 1, wherein the battery having a fixing slot so that the fixing part is rotated into the fixing slot when the battery is set into the handheld device.

6. The device as claimed in claim 1, wherein an accommodating socket is arranged on the handheld device for accommodation of the battery.

7. The device as claimed in claim 6, wherein a plurality of electrode is disposed on the accommodating socket with a waterproof bar arranged on outer side of the electrodes.

8. The device as claimed in claim 6, wherein a groove is disposed on a side wall of the accommodating socket and a projective block is arranged on the battery while the projective block inserts into the groove.

9. The device as claimed in claim 6, wherein at least one projecting post is arranged on the accommodating socket and at least one hole is mounted on the battery while the projecting post matches the hole.

10. The device as claimed in claim 1, wherein the handheld device is a mobile phone.
